(19) United States
(12) Patent Application Publication
(10) Pub. No.: US 2025/0029967 A1
(43) Pub. Date: Jan. 23, 2025

(54) STACKED SEMICONDUCTOR DEVICE WITH EXPANDABLE INTERFACE AND SEMICONDUCTOR PACKAGE INCLUDING THE SAME

(71) Applicant: SK hynix Inc., Gyeonggi-do (KR)

(72) Inventors: Kijoon CHANG, Gyeonggi-do (KR); Wang Su KIM, Gyeonggi-do (KR); Jung Soo PARK, Gyeonggi-do (KR)

(21) Appl. No.: 18/669,537

(22) Filed: May 21, 2024

(30) Foreign Application Priority Data
Jul. 20, 2023 (KR) 10-2023-0094599
Jan. 19, 2024 (KR) 10-2024-0008584

(51) Int. Cl. H01L 25/10; H01L 23/00; H01L 23/538; H10B 80/00

(52) U.S. Cl. CPC H01L 25/105; H01L 23/5385; H01L 24/16; H10B 80/00; H01L 2224/16225

(57) ABSTRACT

A semiconductor package includes a package substrate; an interposer disposed over the package substrate; a stacked semiconductor device including a lower chip and one or more upper chips, which are sequentially stacked over the interposer; a first semiconductor chip stacked over the interposer and spaced apart from the stacked semiconductor device, and configured to interface with the lower chip; and one or more second semiconductor chips disposed over the package substrate to interface with the lower chip.

### CROSS-REFERENCE TO RELATED APPLICATIONS

The present application claims priority to Korean Patent Application Nos. 10-2023-0094599 and 10-2024-0008584, respectively filed on Jul. 20, 2023 and Jan. 19, 2024, which are incorporated herein by reference in their entirety.

### BACKGROUND

### 1. Field

Various embodiments of the present disclosure relate to semiconductor design technology, and more particularly, to an interface method of a stacked semiconductor device.

### 2. Description of the Related Art

As semiconductor technology makes dramatic progress, semiconductor integrated devices such as packages are required to have a higher degree of integration and performance. To this end, current technology is moving away from a two-dimensional structure in which semiconductor chips are arranged on one plane over a printed circuit board (PCB) by using wires or bumps. Instead, new diverse technologies related to a three-dimensional structure in which a plurality of semiconductor chips are vertically stacked are emerging.

The three-dimensional structure may be implemented by a stacked semiconductor device in which a plurality of semiconductor chips are vertically stacked. The semiconductor chips stacked in a vertical direction are electrically connected to each other through through-electrodes (e.g., through-silicon-vias, TSVs) and mounted on a semiconductor packaging substrate.

Recently, various scalable interfaces of a semiconductor package including such a stacked semiconductor device have been discussed.

### SUMMARY

Embodiments of the present disclosure are directed to a stacked semiconductor device having an expandable interface circuit and a semiconductor package including the same.

In accordance with an embodiment of the present disclosure, a semiconductor package includes a package substrate; an interposer disposed over the package substrate; a stacked semiconductor device including a lower chip and one or more upper chips, which are sequentially stacked over the interposer; a first semiconductor chip stacked over the interposer and spaced apart from the stacked semiconductor device, and configured to interface with the lower chip; and one or more second semiconductor chips disposed over the package substrate to interface with the lower chip.

In accordance with an embodiment of the present disclosure, a stacked semiconductor device includes a lower chip; and one or more upper chips stacked over the lower chip, wherein the lower chip includes a first interface circuit to interface with a first semiconductor chip, one or more second interface circuits to interface with one or more second semiconductor chips, and a third interface circuit to interface with the one or more upper chips, and wherein the first interface circuit includes: a main interface logic configured to transmit first signals for the one or more upper chips between the first semiconductor chip and the third interface circuit; and one or more sub-interface logics configured to transmit second signals for the one or more second semiconductor chips between the first semiconductor chip and the one or more second interface circuits.

According to embodiments of the present disclosure, the capacity of a semiconductor package including a stacked semiconductor device may be increased.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a cross-sectional diagram illustrating a semiconductor package including a stacked memory device in accordance with an embodiment of the present disclosure.

FIG. 2 is a perspective view illustrating the stacked memory device shown in FIG. 1 in accordance with an embodiment of the present disclosure.

FIG. 3 is a detailed configuration diagram illustrating a base die shown in FIG. 2 in accordance with an embodiment of the present disclosure.

FIG. 4 is a configuration diagram illustrating a main memory interface logic of a first physical interface circuit of FIG. 3.

FIG. 5 is a detailed configuration diagram illustrating a base die shown in FIG. 2 in accordance with another embodiment of the present disclosure.

FIG. 6 is a detailed configuration diagram illustrating a base die shown in FIG. 2 in accordance with still another embodiment of the present disclosure.

FIGS. 7A and 7B are perspective views illustrating a semiconductor package according to an embodiment of the present disclosure.

### DETAILED DESCRIPTION

Various embodiments of the present disclosure will be described below in more detail with reference to the accompanying drawings. The embodiments teachings may, however, be embodied in different forms and should not be construed as being limited to the embodiments set forth herein. Rather, these embodiments are provided so that this disclosure will convey the scope of the present teachings to those skilled in the art. Throughout this disclosure, like reference numerals refer to like parts throughout the various figures and embodiments of the present disclosure.

It is noted that reference to “an embodiment,” “another embodiment,” or the like does not necessarily mean only one embodiment, and different references to any such phrase are not necessarily to the same embodiment(s).

It will be understood that, although the terms “first,” “second,” “third,” and so on may be used herein to describe various elements, these elements are not limited by these terms. These terms are used to distinguish one element from another element. Thus, a first element described below could also be termed a second or third element without departing from the spirit and scope of the present disclosure.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

As used herein, singular forms may include the plural forms as well, and vice versa, unless the context clearly indicates otherwise. The articles ‘a’ and ‘an’ as used in this application and the appended claims should generally be construed to mean ‘one or more’ unless specified otherwise or it is clear from context to be directed to a singular form.

Hereinafter, a semiconductor system including a stacked semiconductor device will be described. The semiconductor system in accordance with the embodiment of the present disclosure may be embodied in the form of a system-in-package, a multi-chip package, or a system-on-chip, and it may also be embodied in the form of a package-on-package. Hereinafter, a memory system including a stacked memory device will be described as an example of a stacked semiconductor device.

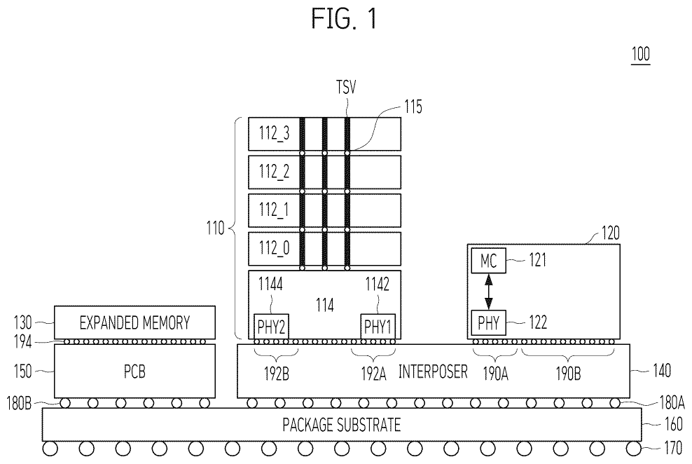

FIG. 1 is a cross-sectional diagram illustrating a semiconductor package 100 including a stacked memory device 110 in accordance with an embodiment of the present disclosure.

Referring to FIG. 1, the semiconductor package 100 may include the stacked memory device 110, a processor 120, an expanded memory 130, an interposer 140, a printed circuit board (PCB) 150, and a package substrate 160.

The package substrate 160 may include a printed circuit board (PCB). A plurality of outer bumps 170 may be disposed on a lower surface of the package substrate 160, and a plurality of inner bumps 180A and 180B may be disposed on an upper surface of the package substrate 160. The plurality of outer bumps 170 may be electrically connected to an external system board, a main board, a module board, or the like. The plurality of outer bumps 170 may include solder balls or metallic bumps. For example, the plurality of outer bumps 170 may include solder balls for supplying power to the stacked memory device 110, the processor 120, and the expanded memory 130, and solder balls for the processor 120 to communicate with the outside. The plurality of inner bumps 180A and 180B may include first inner bumps 180A electrically connecting the package substrate 160 to the interposer 140 and second inner bumps 180B electrically connecting the package substrate 160 to the printed circuit board 150. The plurality of inner bumps 180A and 180B may include solder balls or metallic bumps.

The interposer 140 and the printed circuit board 150 may be mounted onto the package substrate 160. The interposer 140 and the printed circuit board 150 may be disposed on the package substrate 160 spaced apart from each other. The interposer 140 may be a silicon substrate in which only interconnections are formed. The interposer 140 may be electrically connected to the package substrate 160 through the first inner bumps 180A. The printed circuit board 150 may be electrically connected to the package substrate 160 through the second inner bumps 180B.

The stacked memory device 110 and the processor 120 may be mounted onto the interposer 140. The stacked memory device 110 and the processor 120 may be disposed on the interposer 140 spaced apart from each other. Although only one stacked memory device 110 is illustrated in FIG. 1, the embodiments are not limited thereto, and one or more stacked memory devices may be formed on the interposer 140 around the processor 120.

A plurality of processor micro-bumps 190A and 190B may be disposed between the interposer 140 and the processor 120. The plurality of processor micro-bumps 190A and 190B may include solder balls or metallic bumps. The plurality of processor micro-bumps 190A and 190B may include first processor micro-bumps 190A for electrically connecting the processor 120 to the stacked memory device 110 through the interposer 140, and second processor micro-bumps 190B for electrically connecting the processor 120 to an external electronic device through the interposer 140 and the package substrate 160. The first processor micro-bumps 190A may be disposed closer to the stacked memory device 110 than the second processor micro-bumps 190B.

The processor 120 may include a memory controller (MC) 121 and a physical interface (PHY) circuit 122 for an interface with the memory controller 121. The memory controller 121 may be configured to control both the stacked memory device 110 and the expanded memory 130. The physical interface circuit 122 may be connected to the interposer 140 through the first processor micro-bumps 190A to interface between the memory controller 121 and the stacked memory device 110. The physical interface circuit 122 may be used by the memory controller 121 to communicate with the stacked memory device 110. The physical interface circuit 122 may be an interface circuit that converts and outputs signals transferred from the memory controller 121 into signals suitable for use in the stacked memory device 110 or the expanded memory 130, or converts signals transferred from the stacked memory device 110 or the expanded memory 130 into signals suitable for use in the memory controller 121. For reference, the conversion operation may include operations for improving signal quality, such as a serial-to-parallel or parallel-to-serial conversion operation, a buffering operation, an impedance matching operation, a training operation, and an alignment operation. The physical interface circuit mentioned in the following description may be an interface circuit that converts signals transferred from a circuit of a previous stage into signals suitable for use in a circuit of a next stage.

The processor 120 may be one among various processors, such as a micro-processing unit (MPU), a graphic processing unit (GPU), a central processing unit (CPU), and a host processing unit (HPU). The processor 120 may exchange electrical signals with an external processor, power supply, or input/output device through the interposer 140 and the package substrate 160 through the second processor micro-bumps 190B.

A plurality of memory micro-bumps 192A and 192B may be disposed between the interposer 140 and the stacked memory device 110. The plurality of memory micro-bumps 192A and 192B may include solder balls or metallic bumps. The plurality of memory micro-bumps 192A and 192B may include first memory micro-bumps 192A for electrically connecting the stacked memory device 110 and the processor 120 through the interposer 140, and the second memory micro-bumps 192B for electrically connecting the stacked memory device 110 and the expanded memory 130 through the interposer 140, the package substrate 160 and the printed circuit board 150. The first memory micro-bumps 192A may be electrically connected to the first processor micro-bumps 190A through the interconnections inside the interposer 140 and may be disposed closer to the processor 120 than to the second memory micro-bumps 192B. The second memory micro-bumps 192B may be electrically connected to the first inner bumps 180A through the interconnections inside the interposer 140. The first inner bumps 180A may be electrically connected to the second inner bumps 180B through the interconnections inside the package substrate 160. The second inner bumps 180B may be electrically connected to the expanded memory 130 through the interconnections inside the printed circuit board 150. The second memory micro-bumps 192B may be disposed closer to the expanded memory 130 than the first memory micro-bumps 192A. That is, a distance between the second memory micro-bumps 192B and the processor 120 may be greater than a distance between the first memory micro-bumps 192A and the processor 120. Also, a distance between the first memory micro-bumps 192A and the expanded memory 130 may be greater than a distance between the second memory micro-bumps 192B and the expanded memory 130.

The stacked memory device 110 may include a lower chip 114 and one or more upper chips 112_0 to 112_3, which are vertically stacked on the interposer 140. An example of the stacked memory device 110 formed by stacking a plurality of chips as described above may be a high bandwidth memory (HBM). Hereinafter, the lower chip 114 is referred to as a base die 114, and the upper chips 112_0 to 112_3 are referred to as core dies 112_0 to 112_3. In FIG. 1, a case where first to fourth core dies 112_0 to 112_3 are stacked on the base die 114 is illustrated as an example.

Through-electrodes TSV may be formed between the first to fourth core dies 112_0 to 112_3 which are stacked, so that signals (i.e., command, address, and data) may be transferred between the first to fourth core dies 112_0 to 112_3 and the base die 114. A plurality of inter-die micro-bumps 115 may be disposed between the first to fourth core dies 112_0 to 112_3, i.e., between the through-electrodes TSV. The inter-die micro-bumps 115 may electrically connect the through-electrodes TSV between the first to fourth core dies 112_0 to 112_3. The inter-die micro-bumps 115 may include solder balls or metallic bumps.

The base die 114 may include a first physical interface circuit (PHY1) 1142 for interfacing with the memory controller 121, and a second physical interface circuit (PHY2) 1144 for interfacing with the expanded memory 130. In another embodiment, the base die 114 may further include a third physical interface circuit for interfacing with the first to fourth core dies 112_0 to 112_3 through the through-electrodes TSV.

The first physical interface circuit 1142 of the base die 114 may be electrically connected to the physical interface circuit 122 of the processor 120 through the first memory micro-bumps 192A, the interconnections inside the interposer 140, and the first processor micro-bumps 190A. That is, the physical interface circuits 1142 and 122 may be electrically connected to and communicate with each other through the interposer 140. The second physical interface circuit 1144 of the base die 114 may be electrically connected to the printed circuit board 150 through the second memory micro-bumps 192B, the interconnections inside the interposer 140, the first inner bumps 180A, the interconnections inside the package substrate 160, and the second inner bumps 180B.

The expanded memory 130 may be formed on the printed circuit board 150. The expanded memory 130 may include a core area for storing data and input and output (input/output) circuits for an interface with an external device. The input/output circuits of the expanded memory 130 may include a physical interface circuit. The expanded memory 130 may be configured as a low-power double data rate (LPDDR) type dynamic random access memory (DRAM). When the expanded memory 130 is formed on the printed circuit board 150, the expanded memory 130 may have a dual in-line memory module (DIMM) form factor. However, the embodiments are not limited thereto, and the expanded memory 130 may be DDR synchronous DRAM (SDRAM), graphic DDR SDRAM, Rambus DRAM (RDRAM), NAND flash memory, vertical NAND flash memory, NOR flash memory, resistive random access memory (RRAM), phase-change random access memory (PRAM), magnetoresistive random access memory (MRAM), ferroelectric random access memory (FRAM), spin-transfer torque random access memory (STT-RAM), etc. Although only one expanded memory 130 is illustrated in FIG. 1, the embodiments are not limited thereto, and one or more expanded memories may be formed on the printed circuit board 150.

A plurality of expanded micro-bumps 194 may be disposed between the printed circuit board 150 and the expanded memory 130. The plurality of expanded micro-bumps 194 may electrically connect the printed circuit board 150 and the expanded memory 130. The plurality of expanded micro-bumps 194 may include solder balls or metallic bumps.

The expanded memory 130 may be coupled to the printed circuit board 150 through the expanded micro-bumps 194, and the printed circuit board 150 may be coupled to the interposer 140 through its internal interconnections, the second inner bumps 180B, and the first inner bumps 180A. Accordingly, the expanded memory 130 and the second physical interface circuit 1144 may be electrically connected through the interposer 140, the package substrate 160, and the printed circuit board 150, to communicate with each other.

Depending on an embodiment, the interposer 140 and the expanded memory 130 may be disposed on the package substrate 160 spaced apart from each other, and the stacked memory device 110 and the processor 120 may be formed on the interposer 140. That is, the semiconductor package 100 may have a configuration in which the printed circuit board 150 and the expanded micro-bumps 194 are removed from the configuration of FIG. 1. Accordingly, the expanded memory 130 and the second physical interface circuit 1144 may be electrically connected through the interposer 140 and the package substrate 160, to communicate with each other.

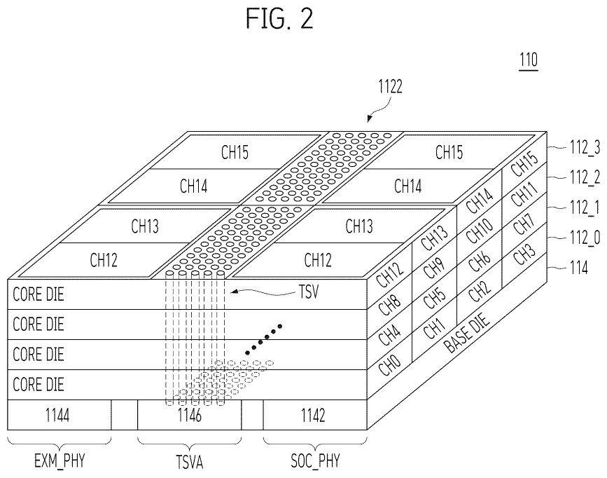

FIG. 2 is a perspective view illustrating the stacked memory device 110 shown in FIG. 1 in accordance with an embodiment of the present disclosure.

Referring to FIG. 2, each of the first to fourth core dies 112_0 to 112_3 may include two or more channels. Each channel may constitute an independent command, address, and data interface. In the example of FIG. 2, as one core die includes four channels, the stacked memory device 110 may have first to 16-th channels CH0 to CH15. For example, the first core die 112_0 may include core areas corresponding to the first to fourth channels CH0 to CH3, and the second core die 112_1 may include core areas corresponding to the fifth to eighth channels CH4 to CH7. The third core die 112_2 may include core areas corresponding to the ninth to 12-th channels CH8 to CH11, and the fourth core die 112_3 may include core areas corresponding to the 13-th to 16-th channels CH12 and CH15. The core area may include a plurality of memory banks including a cell array for storing data, and each memory bank may include memory cells coupled to word lines and bit lines, a row decoder, a column decoder, a sense amplifier, and the like.

Further, a plurality of through-electrodes TSV passing through the first to fourth core dies 112_0 to 112_3 may be disposed in a TSV region 1122 corresponding to the first to 16-th channels CH0 to CH15, respectively. When each channel has a bandwidth of 64 bits, the through-electrodes TSV and corresponding I/O units may be configured to transfer 1024 bits of data.

The base die 114 may communicate with the memory controller 121 of FIG. 1. For example, the base die 114 may transmit signals between the memory controller 121 and the first to fourth core dies 112_0 to 112_3, or transmit signals between the memory controller 121 and the expanded memory 130. The base die 114 may be divided into a first physical area SOC_PHY, a second physical area EXM_PHY, and a TSV area TSVA.

The first physical area SOC_PHY may be provided with an I/O circuit (i.e., the first physical interface circuit 1142 of FIG. 1) for interfacing with the memory controller 121. The first physical area SOC_PHY may be placed in a first edge area of the base die 114, adjacent to the memory controller 121. The second physical area EXM_PHY may be provided with an I/O circuit (i.e., the second physical interface circuit 1144 of FIG. 1) for interfacing with the expanded memory 130. The second physical area EXM_PHY may be placed in a second edge area of the base die 114, adjacent to the expanded memory 130. The second edge area may be disposed in a direction which is opposite to the first edge area, based on the TSV area TSVA. The TSV area TSVA may be provided with an I/O circuit (e.g., a third physical interface circuit 1146) for interfacing with the through-electrodes TSV passing through the first to fourth core dies 112_0 to 112_3. The TSV area TSVA may be placed between the first physical area SOC_PHY and the second physical area EXM_PHY, that is, the TSV area TSVA may be disposed at a central area of the base die 114.

The first physical interface circuit 1142 may transmit signals between the memory controller 121 and the second physical interface circuit 1144, or between the memory controller 121 and the third physical interface circuit 1146. The first physical interface circuit 1142 may transmit signals (e.g., command, address, and data) from the memory controller 121 to the second physical interface circuit 1144 or the third physical interface circuit 1146, and transmit signals (e.g., data) from the second physical interface circuit 1144 or the third physical interface circuit 1146 to the memory controller 121.

The second physical interface circuit 1144 may transmit signals between the first physical interface circuit 1142 and the expanded memory 130. The second physical interface circuit 1144 may transmit signals (e.g., command, address, and data) from the first physical interface circuit 1142 to the expanded memory 130, and transmit signals (e.g., data) from the expanded memory 130 to the first physical interface circuit 1142.

The third physical interface circuit 1146 may transmit signals between the first physical interface circuit 1142 and the first to fourth core dies 112_0 to 112_3 through the through-electrodes TSV. The third physical interface circuit 1146 may transmit signals (e.g., command, address, and data) from the first physical interface circuit 1142 to the fourth core dies 112_0 to 112_3 through the through-electrodes TSV, and transmit signals (e.g., data) from the first to fourth core dies 112_0 to 112_3, to the first physical interface circuit 1142 through the through-electrodes TSV.

Hereinafter, a configuration of the base die 114 according to embodiments of the present disclosure will be described with reference to the drawings. In the following embodiments, a case in which two expanded memories are formed on the printed circuit board 150 will be described as an example.

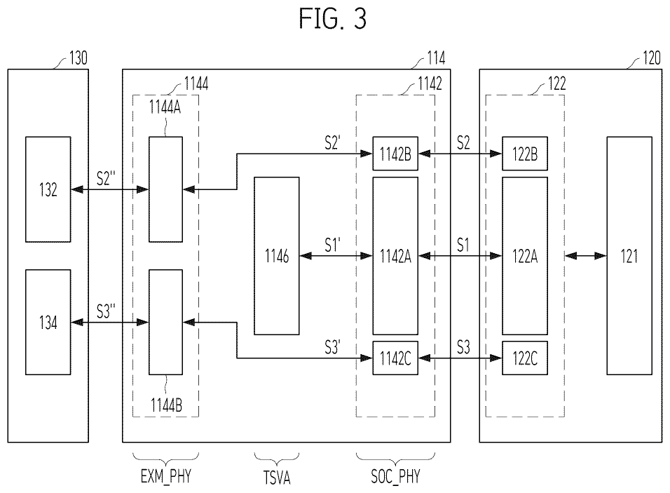

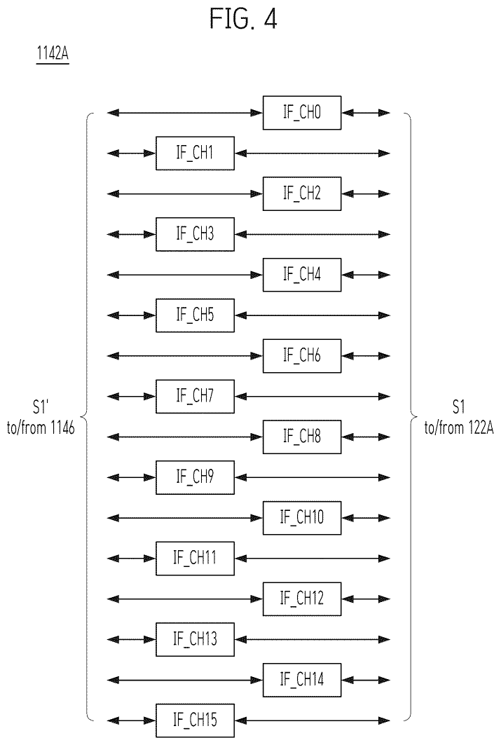

FIG. 3 is a detailed configuration diagram illustrating the base die 114 shown in FIG. 2 in accordance with an embodiment of the present disclosure. FIG. 4 is a configuration diagram illustrating a main memory interface logic 1142A of the first physical interface circuit 1142 of FIG. 3.

Referring to FIG. 3, the memory controller 121 of the processor 120 may generate signals (e.g., command, address, and data) for controlling the stacked memory device 110 and first and second expanded memories 132 and 134, respectively, and transmit the signals to the physical interface circuit 122, or receive signals (e.g., data) transmitted from the physical interface circuit 122.

The physical interface circuit 122 may include a main process interface logic 122A, a first sub-process interface logic 122B, and a second sub-process interface logic 122C. The main process interface logic 122A may transfer first signals S1 for the stacked memory device 110 between the memory controller 121 and the first physical interface circuit 1142. The first sub-process interface logic 122B may transfer second signals S2 for the first expanded memory 132 between the memory controller 121 and the first physical interface circuit 1142. The second sub-process interface logic 122C may transfer third signals S3 for the second expanded memory 134 between the memory controller 121 and the first physical interface circuit 1142.

The first physical interface circuit 1142 of the base die 114 may include a main memory interface logic 1142A, a first sub-memory interface logic 1142B, and a second sub-memory interface logic 1142C. The main memory interface logic 1142A may transfer the first signals S1 and S1′ between the main process interface logic 122A and the third physical interface circuit 1146. The first sub-memory interface logic 1142B may transfer the second signals S2 and S2′ between the first sub-process interface logic 122B and the second physical interface circuit 1144. The second sub-memory interface logic 1142C may transfer the third signals S3 and S3′ between the second sub-process interface logic 122C and the second physical interface circuit 1144. As shown in FIG. 4, the main memory interface logic 1142A may include first to 16-th channel interfaces IF_CH0 to IF_CH15 for interfacing with the first to 16-th channels CH0 to CH15 of the first to fourth core dies 112_0 to 112_3, respectively. The first to 16-th channel interfaces IF_CH0 to IF_CH15 may be electrically connected to the main process interface logic 122A through the first memory micro-bumps 192A of FIG. 1, to transmit and receive the first signals S1, and may be electrically connected to the third physical interface circuit 1146 through the internal interconnections, to transmit and receive the first signals S1′.

The second physical interface circuit 1144 of the base die 114 may include a first expanded memory interface logic 1144A and a second expanded memory interface logic 1144B. The first expanded memory interface logic 1144A may transfer the second signals S2′ and S2″ between the first sub-memory interface logic 1142B and the first expanded memory 132. For example, the first expanded memory interface logic 1144A may perform an operation of converting the second signals S2′ transferred from the first sub-memory interface logic 1142B into the second signals S2″ according to an input/output standard of the first expanded memory 132, or converting the second signals S2″ transferred from the first expanded memory 132 into the second signals S2′ according to an input/output standard of the base die 114. The second expanded memory interface logic 1144B may transfer the third signals S3′ and S3″ between the second sub-memory interface logic 1142C and the second expanded memory 134. For example, the second expanded memory interface logic 1144B may perform an operation of converting the third signals S3′ transferred from the second sub-memory interface logic 1142C into the third signals S3″ according to an input/output standard of the second expanded memory 134, or converting the third signals S3″ transferred from the second expanded memory 134 into the third signals S3′ according to the input/output standard of the base die 114.

For reference, the first signals S1 and S1′ may be signals transmitted according to an input/output standard of a stacked memory device (e.g., HBM) to provide a high bandwidth, and the number of bits of data may be determined according to the bandwidth of the channel (or channel interface) of the core dies. For example, when each channel has a bandwidth of 32 bytes, the first to 16-th channel interfaces IF_CH0 to IF_CH15 may transmit and receive signals in units of 32 bytes, respectively. On the other hand, the second signals S2, S2′ and S2″, and the third signals S3, S3′ and S3″ may be signals transmitted according to an input/output standard of LPDDR type DRAM to provide low power consumption. For example, the number of bits of data may be transmitted and received in units of 32 bytes or less. That is, the second signals S2, S2′ and S2″, and the third signals S3, S3′ and S3″ may be transmitted with a lower bandwidth than the first signals S1 and S1′.

The operation of the base die 114 having the above configuration will be described as follows.

During a write operation, the memory controller 121 may generate signals for controlling the stacked memory device 110, and the main process interface logic 122A may transmit the first signals S1 to the main memory interface logic 1142A. The main memory interface logic 1142A may convert the first signals S1 to transmit the first signals S1′ to the third physical interface circuit 1146, and the third physical interface circuit 1146 may transmit the first signals S1′ to the first to fourth core dies 112_0 to 112_3 through the through-electrodes TSV. Alternatively, the memory controller 121 may generate signals for controlling the first expanded memory 132 and/or the second expanded memory 134, the first sub-process interface logic 122B may transmit the second signals S2 to the first sub-memory interface logic 1142B, and the second sub-process interface logic 122C may transmit the third signals S3 to the second sub-memory interface logic 1142C. The first sub-memory interface logic 1142B may convert the second signals S2 to transmit the second signals S2′ to the first expanded memory interface logic 1144A, and the first expanded memory interface logic 1144A may convert the second signals S2′ to transmit the second signals S2″ to the first expanded memory 132. Likewise, the second sub-memory interface logic 1142C may convert the third signals S3 to transmit the third signals S3′ to the second expanded memory interface logic 1144B, and the second expanded memory interface logic 1144B may convert the third signals S3′ to transmit the third signals S3″ to the second expanded memory 134.

During a read operation, the third physical interface circuit 1146 may transmit, to the main memory interface logic 1142A, the first signals S1′ transferred from the first to fourth core dies 112_0 to 112_3 through the through-electrodes TSV, and the main memory interface logic 1142A may convert the first signals S1′ to transmit the first signals S1 to the processor 120. The first expanded memory interface logic 1144A may convert the second signals S2″ transferred from the first expanded memory 132 to transmit the second signals S2′ to the first sub-memory interface logic 1142B, and the first sub-memory interface logic 1142B may convert the second signals S2′ to transmit the second signals S2 to the processor 120. Likewise, the second expanded memory interface logic 1144B may convert the third signals S3″ transferred from the second expanded memory 134 to transmit the third signals S3′ to the second sub-memory interface logic 1142C, and the second sub-memory interface logic 1142C may convert the third signals S3′ to transmit the third signals S3 to the processor 120.

For reference, during the write operation or the read operation, the first signals S1 and S1′, the second signals S2, S2′ and S2″, and the third signals S3, S3′ and S3″ may be transmitted simultaneously or separately.

As described above, in accordance with an embodiment of the present disclosure, an expandable interface circuit is disposed on the base die 114 of the stacked memory device 110 to connect additional expanded memories 132 and 134, and the memory controller 121 may control both the stacked memory device 110 and the expanded memories 132 and 134. That is, the capacity of the semiconductor package may be expanded by connecting additional expanded memories in the semiconductor package.

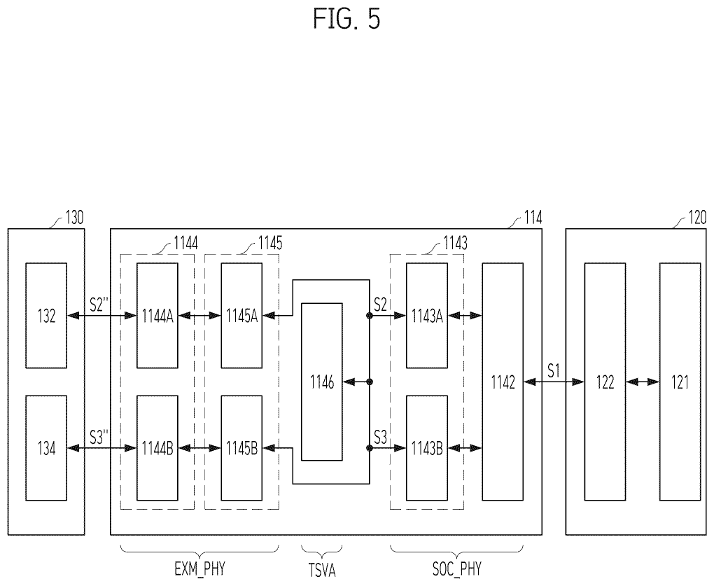

FIG. 5 is a detailed configuration diagram illustrating the base die 114 shown in FIG. 2 in accordance with another embodiment of the present disclosure.

Referring to FIG. 5, the memory controller 121 may generate signals (e.g., command, address, and data) for controlling the stacked memory device 110 and first and second expanded memories 132 and 134, respectively, and transmit the signals to the physical interface circuit 122, or receive signals (e.g., data) transmitted from the physical interface circuit 122. The physical interface circuit 122 may transmit signals S1 for controlling the stacked memory device 110 and the first and second expanded memories 132 and 134 between the memory controller 121 and the first physical interface circuit 1142.

The base die 114 according to an embodiment of FIG. 5 may further include an arbitrator 1143 and an expanded controller 1145, in addition to the first to third physical interface circuits 1142 to 1146 as shown in FIG. 3.

The arbitrator 1143 may receive signals S1 transmitted from the first physical interface circuit 1142 and determine whether the input signals S1 correspond to the core dies of the stacked memory device 110 or the expanded memories 132 and 134. The arbitrator 1143 may transmit the input signals S1 to the third physical interface circuit 1146 or the expanded controller 1145, according to the determination result. In addition, the arbitrator 1143 may receive signals S2 and S3 transmitted from the third physical interface circuit 1146 or the expanded controller 1145, and transmit the signals S2 and S3 to the first physical interface circuit 1142. The arbitrator 1143 may include a first arbitration logic 1143A and a second arbitration logic 1143B corresponding to the first expanded memory 132 and the second expanded memory 134, respectively. The arbitrator 1143 may be disposed in the first physical area SOC_PHY together with the first physical interface circuit 1142.

The expanded controller 1145 may include a first expanded control logic 1145A and a second expanded control logic 1145B corresponding to the first expanded memory 132 and the second expanded memory 134, respectively. The first expanded control logic 1145A may generate signals (e.g., command, address, and data) for controlling the first expanded memory 132 according to the signals S2 transmitted from the first arbitration logic 1143A, and schedule and transmit the generated signals to the second physical interface circuit 1144, or transmit signals (e.g., data) provided from the second physical interface circuit 1144 to the first arbitration logic 1143A. The second expanded control logic 1145B may generate signals (e.g., command, address, and data) for controlling the second expanded memory 134 according to the signals S3 transmitted from the second arbitration logic 1143B, and schedule and transmit the generated signals to the second physical interface circuit 1144, or transmit signals (e.g., data) provided from the second physical interface circuit 1144 to the second arbitration logic 1143B. The expanded controller 1145 may be disposed in the second physical area EXM_PHY together with the second physical interface circuit 1144.

The second physical interface circuit 1144 may include a first expanded memory interface logic 1144A and a second expanded memory interface logic 1144B. The first expanded memory interface logic 1144A may transfer signals S2″ between the first expanded control logic 1145A and the first expanded memory 132. The second expanded memory interface logic 1144B may transfer signals S3″ between the second expanded control logic 1145B and the second expanded memory 134.

The operation of the base die 114 having the above configuration will be described as follows.

During a write operation, when the signals S1 corresponding to the core dies of the stacked memory device 110 are transmitted from the processor 120, the first physical interface circuit 1142 may convert and transmit the signals S1 to the first arbitration logic 1143A and the second arbitration logic 1143B, and the first arbitration logic 1143A and the second arbitration logic 1143B may transmit the signals S2 and S3 to the third physical interface circuit 1146. On the other hand, when the signals S1 corresponding to the first expanded memory 132 are transmitted from the processor 120, the first physical interface circuit 1142 may convert and transmit the signals S1 to the first arbitration logic 1143A, and the first arbitration logic 1143A may transmit the signals S2 to the first expanded control logic 1145A. The first expanded control logic 1145A may generate signals (e.g., command, address, and data) for controlling the first expanded memory 132 according to the signals S2, and schedule and transmit the signals to the first expanded memory 132 through the second physical interface circuit 1144. Substantially the same write operation may be performed on the second expanded memory 134.

During a read operation, the third physical interface circuit 1146 may transmit the signals S2 and S3 transmitted from the core dies through the through-electrodes TSV to the first arbitration logic 1143A and the second arbitration logic 1143B. The first arbitration logic 1143A and the second arbitration logic 1143B may transmit the signals S2 and S3 to the first physical interface circuit 1142, and the first physical interface circuit 1142 may transmit the signals S1 to the processor 120. On the other hand, the first expanded memory interface logic 1144A may convert the signals S2″ transmitted from the first expanded memory 132 to the first expanded control logic 1145A, and the first expanded control logic 1145A may transmit the signals S2 to the first arbitration logic 1143A. The first arbitration logic 1143A may transmit the signals S2 to the first physical interface circuit 1142, and the first physical interface circuit 1142 may transmit the signals S1 to the processor 120. Substantially the same read operation may be performed on the second expanded memory 134.

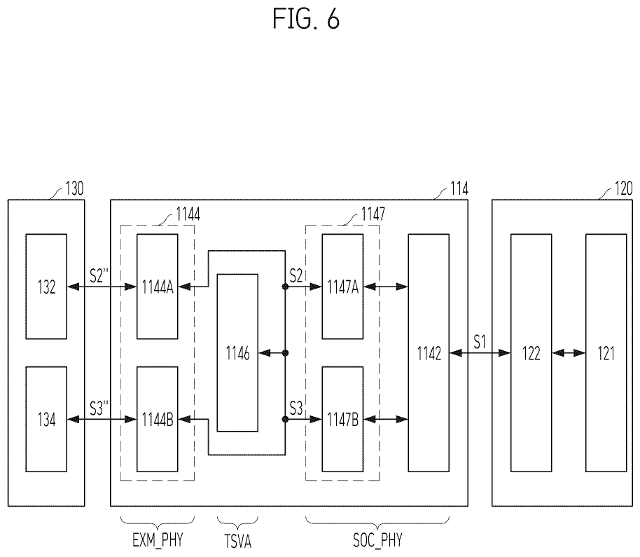

FIG. 6 is a detailed configuration diagram illustrating the base die 114 shown in FIG. 2 in accordance with still another embodiment of the present disclosure.

Referring to FIG. 6, the memory controller 121 may generate signals (e.g., command, address, and data) for controlling the stacked memory device 110 and first and second expanded memories 132 and 134, respectively, and transmit the signals to the physical interface circuit 122, or receive signals (e.g., data) transmitted from the physical interface circuit 122. The physical interface circuit 122 may transmit signals S1 for controlling the stacked memory device 110 and the first and second expanded memories 132 and 134 between the memory controller 121 and the first physical interface circuit 1142.

The base die 114 according to an embodiment of FIG. 6 may further include a path controller 1147, in addition to the first to third physical interface circuits 1142 to 1146. The path controller 1147 may determine whether the signals S1 transmitted from the first physical interface circuit 1142 correspond to the core dies of the stacked memory device 110 or the expanded memories 132 and 134. The path controller 1147 may transmit the input signals S1 to the second physical interface circuit 1144 or the third physical interface circuit 1146, or transmit signals S2 and S3 from the second physical interface circuit 1144 or the third physical interface circuit 1146, to the first physical interface circuit 1142, according to the determination result. The path controller 1147 may be disposed in the first physical area SOC_PHY together with the first physical interface circuit 1142.

The path controller 1147 may include a first path control logic 1147A and a second path control logic 1147B corresponding to the first expanded memory 132 and the second expanded memory 134, respectively. The first path control logic 1147A and the second path control logic 1147B may determine whether the signals S1 transferred from the first physical interface circuit 1142 correspond to the core dies of the stacked memory device 110 or the expanded memories 132 and 134.

Depending on the determination result, the first path controller 1147A may transmit the input signals S1 to the second physical interface circuit 1144 or the third physical interface circuit 1146, or transmit the signals S2 from the second physical interface circuit 1144 or the third physical interface circuit 1146, to the first physical interface circuit 1142. For example, if it is determined that the input signals S1 correspond to the first expanded memory 132, the first path control logic 1147A may generate signals for controlling the first expanded memory 132, and schedule and transmit the signals S2 to the second physical interface circuit 1144.

Depending on the determination result, the second path controller 1147B may transmit the input signals S1 to the second physical interface circuit 1144 or the third physical interface circuit 1146, or transmit the signals S3 from the second physical interface circuit 1144 or the third physical interface circuit 1146, to the first physical interface circuit 1142. For example, if it is determined that the signals S1 correspond to the second expanded memory 134, the second path control logic 1147B may generate signals for controlling the second expanded memory 134, and schedule and transmit the signals S3 to the second physical interface circuit 1144.

According to an embodiment, the path controller 1147 may further include an encryption key storage that stores a plurality of encryption keys. The path controller 1147 may select one of the encryption keys stored in the encryption key storage during boot-up, and encrypt the signals S1 transmitted from the first physical interface circuit 1142 using the selected encryption key to transmit the signals S2 (i.e., encrypted signals) to the second physical interface circuit 1144 or the third physical interface circuit 1146. In addition, the path controller 1147 may decrypt the signals S2 and S3 transmitted from the second physical interface circuit 1144 or the third physical interface circuit 1146 using the selected encryption key and transmit the signals S2 and S3 (i.e., decrypted signals) to the first physical interface circuit 1142.

According to an embodiment, the path controller 1147 may further include a power storage that stores a plurality of voltage states. The path controller 1147 may select one of the plurality of voltage states by verifying the power consumption of the stacked memory device 110 and the expanded memories 132 and 134, and control power distribution of the stacked memory device 110 and the expanded memories 132 and 134 according to the selected voltage state. For example, if it is determined that the power consumed by the stacked memory device 110 increases, the path controller 1147 may select a voltage state for increasing the power provided to the stacked memory device 110.

The second physical interface circuit 1144 may include a first expanded memory interface logic 1144A and a second expanded memory interface logic 1144B. The first expanded memory interface logic 1144A may transfer signals S2 and S2″ between the first path control logic 1147A and the first expanded memory 132. The second expanded memory interface logic 1144B may transfer signals S3 and S3″ between the second path control logic 1147B and the second expanded memory 134.

The operation of the base die 114 having the above configuration will be described as follows.

During a write operation, when the signals S1 corresponding to the core dies of the stacked memory device 110 are transmitted from the processor 120, the first physical interface circuit 1142 may convert the signals S1 to transmit the signals to the first path control logic 1147A and the second path control logic 1147B, and the first path control logic 1147A and the second path control logic 1147B may transmit the signals S2 and S3 to the third physical interface circuit 1146. On the other hand, when the signals S1 corresponding to the first expanded memory 132 are transmitted from the processor 120, the first physical interface circuit 1142 may convert and transmit the signals S1 to the first path control logic 1147A, and the first path control logic 1147A may generate signals (e.g., command, address, and data) for controlling the first expanded memory 132, and schedule and transmit the signals S2 to the first expanded memory interface logic 1144A. Substantially the same write operation may be performed on the second expanded memory 134.

During a read operation, the third physical interface circuit 1146 may transmit the signals S2 and S3 transmitted from the core dies through the through-electrodes TSV to the first path control logic 1147A and the second path control logic 1147B. The first path control logic 1147A and the second path control logic 1147B may transmit the signals to the first physical interface circuit 1142, and the first physical interface circuit 1142 may transmit the signals S1 to the processor 120. The first expanded memory interface logic 1144A may convert the signals S2″ transferred from the first expanded memory 132 to transmit the signals S2 to the first path control logic 1147A, and the first physical interface circuit 1142 may transmit the first signals S1 to the processor 120. Substantially the same read operation may be performed on the second extension memory 134.

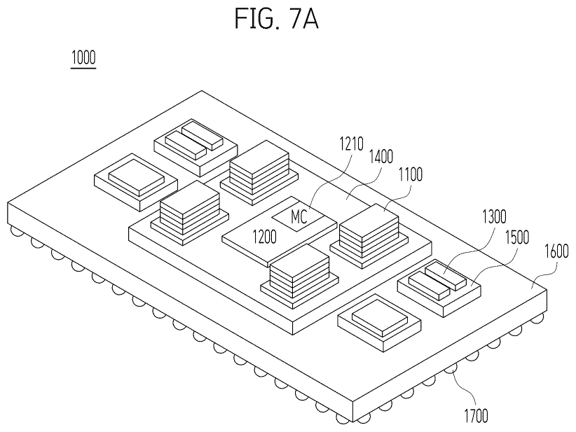

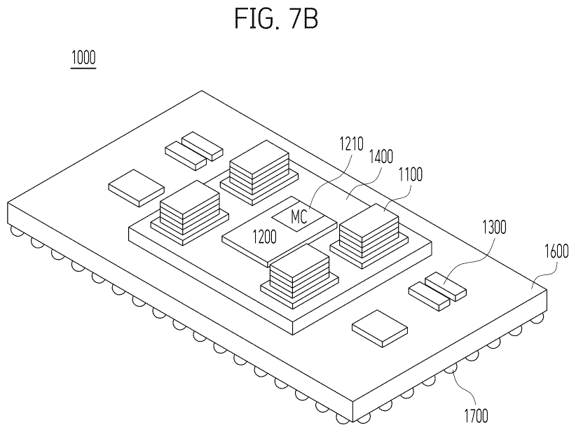

FIGS. 7A and 7B are perspective views illustrating a semiconductor package 1000 according to an embodiment of the present disclosure.

Referring to FIG. 7A, the semiconductor package 1000 may include a plurality of stacked memory devices 1100, a processor 1200, a plurality of expanded memories 1300, an interposer 1400, a plurality of printed circuit boards 1500, and a package board 1600.

A plurality of external bumps 1700 may be disposed on a bottom surface of the package board 1600. The interposer 1400 and the printed circuit boards 1500 (e.g., four printed circuit boards 1500) may be formed on a top surface of the package board 1600. The interposer 1400 and the printed circuit boards 1500 may be disposed on the package board 1600 spaced apart from each other.

The stacked memory devices 1100 (e.g., four stacked memory devices 1100) may be formed symmetrically around the processor 1200. The stacked memory devices 1100 and the processor 1200 may be disposed on the interposer 1400 spaced apart from each other. The processor 1200 may include a memory controller (MC) 1210, and the memory controller 1210 may be electrically connected to the stacked memory devices 1100 through a physical interface circuit, for example, a physical interface circuit of FIGS. 1-6 as described above. For example, the processor 1200 may include four physical interface circuits corresponding to the four stacked memory devices 1100, respectively.

Each of the stacked memory devices 1100 may include a base die and one or more core dies stacked vertically on the interposer 1400. Each base die may be electrically connected to one physical interface circuit of the processor 1200 through a first physical interface circuit, and may be electrically connected to a printed circuit board 1500 through a second physical interface circuit.

The plurality of expanded memories 1300 may be formed on each of the printed circuit boards 1500. One or more expanded memories 1300 may be electrically connected to the second physical interface circuit of the base die through the printed circuit board 1500, the package board 1600 and the interposer 1400. Accordingly, the expanded memories 1300 and the second physical interface circuit of the base die may be electrically connected through the interposer 1400, the package board 1600 and the printed circuit board 1500, to communicate with each other.

According to an embodiment, the semiconductor package 1000 may have a configuration in which the printed circuit boards 1500 are removed from the semiconductor package 1000 of FIG. 7A. That is, referring to FIG. 7B, the semiconductor package 1000 may include a plurality of stacked memory devices 1100, a processor 1200, a plurality of expanded memories 1300, an interposer 1400, and a package substrate 1600. The interposer 1400 and the expanded memories 1300 may be disposed on the package substrate 1600 spaced apart from each other, and the stacked memory devices 1100 and the processor 1200 may be formed on the interposer 1400. Accordingly, the expanded memories 1300 and the second physical interface circuit of the base die may be electrically connected through the interposer 1400 and the package substrate 1600 to communicate with each other.

While the embodiments of the present disclosure have been described with respect to specific embodiments, it will be apparent to those skilled in the art that various changes and modifications may be made without departing from the spirit and scope of the present disclosure as defined in the following claims.

For example, the logic gates and transistors described in the above embodiments may have different positions and types according to the polarity of input signals. Furthermore, the embodiments may be combined to form additional embodiments.

What is claimed is:

1. A semiconductor package, comprising:
a package substrate;
an interposer disposed over the package substrate;
a stacked semiconductor device including a lower chip and one or more upper chips, which are sequentially stacked over the interposer;
a first semiconductor chip stacked over the interposer and spaced apart from the stacked semiconductor device, and configured to interface with the lower chip; and
one or more second semiconductor chips disposed over the package substrate to interface with the lower chip.

2. The semiconductor package of claim 1, wherein the lower chip includes:
a first interface circuit placed in a first area to interface with the first semiconductor chip through the interposer; and
one or more second interface circuits that are placed in a second area to interface with the one or more second semiconductor chips through the interposer and the package substrate.

3. The semiconductor package of claim 2,
wherein the first area is disposed closer to the first semiconductor chip than the one or more second semiconductor chips, and
wherein the second area is disposed closer to the one or more second semiconductor chips than the first semiconductor chip.

4. The semiconductor package of claim 3, wherein the lower chip further includes a third interface circuit placed between the first area and the second area to interface with the one or more upper chips through through-electrodes.

5. The semiconductor package of claim 4, wherein the first interface circuit includes:
a main interface logic configured to transmit first signals for the one or more upper chips between the first semiconductor chip and the third interface circuit; and
one or more sub-interface logics configured to transmit second signals for the one or more second semiconductor chips between the first semiconductor chip and the one or more second interface circuits.

6. The semiconductor package of claim 5, wherein the second signals are transmitted at a bandwidth lower than the first signals.

7. The semiconductor package of claim 5,
wherein each of the one or more upper chips includes a plurality of channels, and
wherein the main interface logic includes a plurality of channel interfaces which correspond to the plurality of channels, respectively, and each of which inputs and outputs signals with a corresponding channel.

8. The semiconductor package of claim 4, wherein the lower chip further includes:
an arbitrator configured to determine whether signals input from the first interface circuit correspond to the one or more upper chips or the one or more second semiconductor chips, and provide the input signals to the third interface circuit or one or more expanded controllers according to the determination result; and
the one or more expanded controllers configured to generate signals corresponding to the one or more second semiconductor chips according to the input signals transmitted from the arbitrator, and transmit the generated signals to the second interface circuit.

9. The semiconductor package of claim 4, wherein the lower chip further includes one or more path controllers configured to determine whether signals input from the first interface circuit correspond to the one or more upper chips or the one or more second semiconductor chips, and provide the input signals to the second interface circuit or the third interface circuit according to the determination result.

10. The semiconductor package of claim 1, further comprising:
a printed circuit board disposed over the package substrate, spaced apart from the interposer,
wherein the one or more second semiconductor chips are disposed over the printed circuit board.

11. The semiconductor package of claim 1,
wherein the stacked semiconductor device includes a high bandwidth memory (HBM), and the lower chip includes a base die of the HBM.

12. The semiconductor package of claim 1,
wherein the first semiconductor chip includes a memory controller, and the one or more second semiconductor chips include a low-power double data rate (LPDDR) type dynamic random access memory (DRAM).

13. The semiconductor package of claim 1, further comprising:
a plurality of first micro-bumps disposed between the interposer and the lower chip and electrically connected to the first semiconductor chip through the interposer; and
a plurality of second micro-bumps disposed between the interposer and the lower chip and electrically connected to the one or more second semiconductor chips through the interposer and the package substrate.

14. The semiconductor package of claim 13,
wherein a distance between the second micro-bumps and the first semiconductor chip is greater than that between the first micro-bumps and the first semiconductor chip, and
wherein a distance between the first micro-bumps and the one or more second semiconductor chips is greater than that of the second micro-bumps and the one or more second semiconductor chips.

15. A stacked semiconductor device, comprising:
a lower chip; and
one or more upper chips stacked over the lower chip,
wherein the lower chip includes a first interface circuit to interface with a first semiconductor chip, one or more second interface circuits to interface with one or more second semiconductor chips, and a third interface circuit to interface with the one or more upper chips, and
wherein the first interface circuit includes:
a main interface logic configured to transmit first signals for the one or more upper chips between the first semiconductor chip and the third interface circuit; and
one or more sub-interface logics configured to transmit second signals for the one or more second semiconductor chips between the first semiconductor chip and the one or more second interface circuits.

16. The stacked semiconductor device of claim 15,
wherein the stacked semiconductor device and the first semiconductor chip are disposed over an interposer disposed on a package substrate, and
wherein the one or more second semiconductor chips are disposed over the package substrate.

17. The stacked semiconductor device of claim 15,
wherein the stacked semiconductor device and the first semiconductor chip are disposed over an interposer, and
wherein the one or more second semiconductor chips are spaced apart from the interposer and disposed over a printed circuit board that is spaced apart from the interposer.

18. The stacked semiconductor device of claim 15,
wherein the first interface circuit is disposed in a first area that is placed closer to the first semiconductor chip than the one or more second semiconductor chips,
wherein the second interface circuit is disposed in a second area that is placed closer to the one or more second semiconductor chips than the first semiconductor chip, and
wherein the third interface circuit is disposed between the first area and the second area.

19. The stacked semiconductor device of claim 15, wherein the second signals are transmitted at a bandwidth lower than the first signals.

20. The stacked semiconductor device of claim 15, wherein the lower chip further includes:
an arbitrator configured to determine whether signals input from the first interface circuit correspond to the one or more upper chips or the one or more second semiconductor chips, and provide the input signals to the third interface circuit or one or more expanded controllers according to the determination result; and
the one or more expanded controllers configured to generate signals corresponding to the one or more second semiconductor chips according to the input signals transmitted from the arbitrator, and transmit the generated signals to the second interface circuit.

21. The stacked semiconductor device of claim 15, wherein the lower chip further includes
one or more path controllers configured to determine whether signals input from the first interface circuit correspond to the one or more upper chips or the one or more second semiconductor chips, and provide the input signals to the second interface circuit or the third interface circuit according to the determination result.

22. The stacked semiconductor device of claim 21, wherein each of the path controllers encrypts the signals input from the first interface circuit using an encryption key selected among a plurality of encryption keys.

23. The stacked semiconductor device of claim 21, wherein each of the path controllers stores a plurality of voltage states, selects one of the plurality of voltage states by verifying a power consumption of the stacked semiconductor device and the one or more second semiconductor chips, and controls power distribution of the stacked semiconductor device and the one or more second semiconductor chips according to the selected voltage state.
